(19) United States
(12) Patent Application Publication
(10) Pub. No.: US 2015/0091876 A1
(43) Pub. Date: Apr. 2, 2015

(54) CURVED DISPLAY APPARATUS WITH SAFETY BUTTON

(71) Applicant: Hyundai Motor Company, Seoul (KR)

(72) Inventor: Jong Bok Lee, Suwon (KR)

(73) Assignee: HYUNDAI MOTOR COMPANY, Seoul (KR)

(21) Appl. No.: 14/143,617

(22) Filed: Dec. 30, 2013

(30) Foreign Application Priority Data
Sep. 27, 2013 (KR) 10-2013-0115195

(51) Int. Cl. G06F 3/02; H01L 41/09; G06F 3/041

(52) U.S. Cl. CPC G06F 3/0227; G06F 3/0412; G06F 3/0418; H01L 41/09
USPC 345/178

(57) ABSTRACT

A curved display with a safety button is provided. The curved display includes a curved screen that displays an image and a safety button that includes a plurality of piezo actuators arranged at predetermined intervals along a guide part on the curved screen. A controller is configured to operate equipment within a vehicle based on sensing the piezo actuators are sensed and operate the piezo actuators. Since the piezo actuators are arranged at predetermined intervals on the front of the curved screen, a physical button works even when a touch sensor fails.

### CROSS-REFERENCE TO RELATED APPLICATION

This application claims priority to and the benefit of Korean Patent Application No. 10-2013-0115195 filed in the Korean Intellectual Property Office on Sep. 27, 2013, the entire contents of which are incorporated herein by reference.

### BACKGROUND

(a) Field of the Invention

The present invention relates to a curved display with a safety button. More particularly, the present invention relates to a curved display with a safety button that ensures safety with a button using a piezo actuator used when the curved display fails to recognize a user touch.

(b) Description of the Related Art

With the increase in quality and variation of vehicle functions, various input devices for inputting commands various functions of the vehicles have been developed. Recently, an attempt to use a touch screen for the cluster or the AVN (Audio Video Navigation) of vehicles has been developed. In general, since the touch screens mounted within vehicles are positioned ahead of the driver's seat, the spatial use is not efficient. Further, the touch screens are not designed for the curved design of mounting locations within the vehicles. Those curved displays mounted within vehicles require a device for recognizing a user touch and do not recognize a touch by common objects. For such a demand, a technology that recognizes a touch by a user, using infrared light has been used in the related art.

FIG. 1 is an exemplary diagram illustrating the configuration of a curved display that recognizes a user touch for curved displays according to the related art. As illustrated in the figure, the curved display includes a curved screen 10, a projector 20 disposed behind the curved screen 10 and configured to project an image onto the curved screen 10, an aspheric mirror 30 configured to reflect the image projected from the projector 20, and a reflective mirror 40 configured to transfer the image reflecting from the aspheric mirror 30 to the curved screen 10. To recognize a user touch on the curved screen 10, infrared light is emitted from an infrared lamp 70 behind the curved screen 10 and an infrared image reflecting from the curved screen 10 is captured by an infrared imaging device 50. Whether a user has touched the curved screen 10 is determined by analyzing the captured infrared image.

In general, in curved displays, there is no physical button and various commands are input via a user interface. However, a physical button may be required for the curved displays when the ability to sense a user touch fails, or various other reasons. Accordingly, as shown in FIG. 2, in the related art, a dial type safety button 90 is disposed on the curved screen 10 and an infrared marker 91 is disposed on the rear of the safety button 90. Further, the infrared imaging device 50 has been used to determine whether the safety button 90 turns or the turning angle. However, according to the related art described above, when external light travels into the safety button 90 in the curved screen 10, or when a touch sensor fails due to a failure of the infrared imaging device 50, the safety button 90 may not be used.

The above information disclosed in this section is only for enhancement of understanding of the background of the invention and therefore it may contain information that does not form the prior art that is already known in this country to a person of ordinary skill in the art.

### SUMMARY

The present invention provides a curved display having a safety button that allows stable operation of a physical button in a curved display. Further, the present invention may improve a user interface by providing haptic feedback based on the operation region of a safety button.

An exemplary embodiment of the present invention provides a curved display with a safety button that may include: a curved screen configured to display an image; a safety button that includes a plurality of piezo actuators disposed at regular intervals along a guide part on the curved screen; and a controller configured to operate equipment within a vehicle based on the sensed piezo actuators and operates the piezo actuators.

The controller may be further configured to adjust control gaps of equipment within a vehicle by measuring the sensing time of adjacent piezo actuators. When the safety button is provided for operating the volume of audio equipment, the controller may be configured to adjust the volume control gaps of the audio equipment based on the sensing time of the piezo actuators. When the safety button is provided for the temperature of an air conditioner, the controller may be configured to adjust the temperature control gaps of the air conditioner based on the sensing time of the piezo actuators. When a particular piezo actuator is sensed, the controller may be configured to provide haptic feedback through the piezo actuator. A mark showing the operation direction of the safety button may be displayed on the guide part.

### BRIEF DESCRIPTION OF THE DRAWINGS

The drawings are provided for reference in describing exemplary embodiments of the present invention and the spirit of the present invention should not be construed only by the accompanying drawings.

FIG. 1 is an exemplary schematic diagram illustrating the configuration of a common curved display according to the related art;

FIG. 2 is an exemplary schematic view illustrating the configuration of a safety button of a curved display according to the related art;

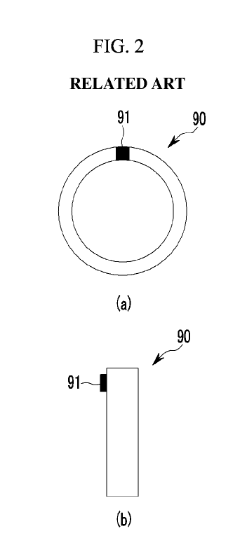

FIG. 3 is an exemplary schematic view illustrating the configuration of a curved display with a safety button according to an exemplary embodiment of the present invention;

FIG. 4 is an exemplary schematic diagram illustrating the configuration of a safety button of a curved display according to an exemplary embodiment of the present invention; and

FIG. 5 is an exemplary schematic diagram illustrating a voltage change in relation to time during operation of a safety button of a curved display according to an exemplary embodiment of the present invention.

Description of symbols

| | |
|---|---|
| 10: curved screen | 20: projector |
| 30: aspheric mirror | 40: reflective mirror |
| 51: infrared lamp | 53: infrared imaging device |
| 60: safety button | 61, 62, 63, 64, 65, 66, 67, 68: piezo actuator |
| 69: guide part | 70: controller |
| 81: audio device | 82: air conditioner |

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, combustion, plug-in hybrid electric vehicles, hydrogen-powered vehicles and other alternative fuel vehicles (e.g. fuels derived from resources other than petroleum).

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

Furthermore, control logic of the present invention may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. The unrelated parts to the description of the exemplary embodiments are not shown to make the description clear and like reference numerals designate like element throughout the specification.

The sizes and thicknesses of the configurations shown in the drawings are provided selectively for the convenience of description, such that the present invention is not limited to those shown in the drawings and the thicknesses are exaggerated to make some parts and regions clear.

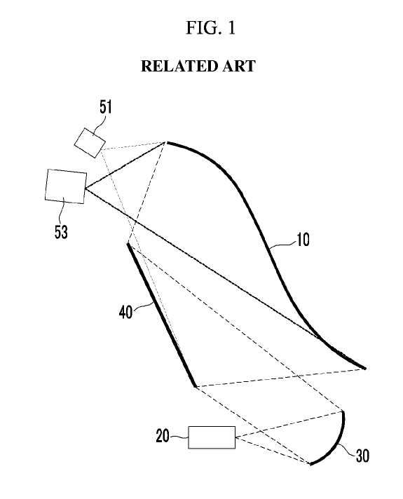

FIG. 1 is an exemplary schematic diagram of a common curved display according to the related art. As shown in FIG. 1, a curved display includes a curved screen 10 configured to display an image, a projector 20 disposed behind the curved screen 10 and configured to project an image onto the curved screen 10, an aspheric mirror 30 configured to reflect the image projected from the projector 20, and a reflective mirror 40 configured to transfer the image reflected from the aspheric mirror 30 to the curved screen 10.

The projector 20 may be configured to receive light produced by a light source (not shown) that generates an image to be displayed on the curved screen 10 and project the light to the curved screen 10. The curved screen 10 may be made of an acryl plate and a rear transmission film bonded to the acryl plate. To mount the curved screen 10 to the front part within a vehicle (e.g., a front location within the vehicle), a bezel may be fitted in an edge of the curved screen and may be fixed to the front part within a vehicle. The aspheric mirror 30 and the reflective mirror 40 may be disposed between the projector 20 and the curved screen 10. In other words, the light from the projector 20 may be configured to reflect from the aspheric mirror 30 and travel to the reflective mirror 40. The light may reflect from the reflective mirror 40 to the curved screen 10 to display an image.

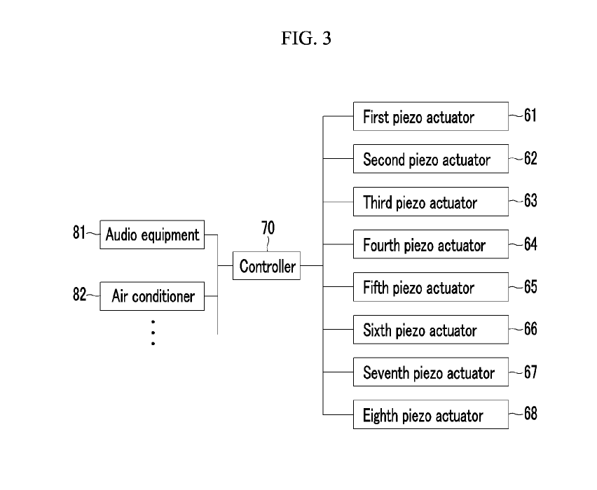

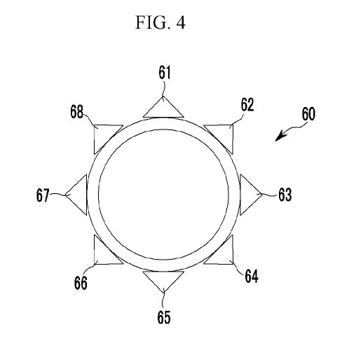

FIG. 3 is an exemplary conceptual diagram illustrating the configuration of a curved display having a safety button according to an exemplary embodiment of the present invention. FIG. 4 is an exemplary schematic diagram illustrating the configuration of a safety button of a curved display according to an exemplary embodiment of the present invention.

A safety button disposed on a curved display according to an exemplary embodiment of the present invention may include a guide part on the curved screen, a safety button that includes a plurality of piezo actuators disposed at regular intervals along the guide part, and a controller configured to operate equipment within a vehicle based on whether operation of the piezo actuator is sensed and operate the piezo actuators.

The guide part may be shaped as a ring on the curved screen for operational convenience of a user. Further, if necessary, the guide part may be formed in the shape of a bar or other various shapes. In addition, guide marks that showing operation directions may be displayed on the guide part. For example, when the safety button is to adjust the volume of audio equipment, a user may operate the safety button by a displayed mark such as an arrow in the direction of increasing or decreasing the volume. The piezo actuators may be devices that may deform when a voltage is generated by displacement or a voltage is applied, and may be used to sense a user touch or provide haptic feedback to a user. The piezo actuators may be arranged at regular (predetermined) intervals along the guide part, and when a user sequentially touches the piezo actuators, the controller may be configured to determine changes in voltage based on sensing the piezo actuators and the speed of sensing the piezo actuators.

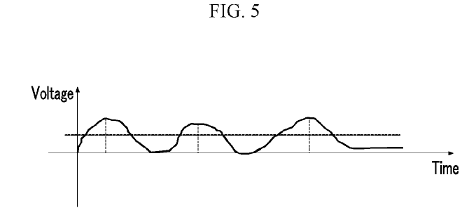

FIG. 5 is an exemplary schematic diagram illustrating a voltage change in relation to time during operation of a safety button of a curved display according to an exemplary embodiment of the present invention. As shown in FIG. 5, signals showing the piezo actuators sequentially arranged along the guide part show substantially sine waves. Accordingly, it may be possible to determine whether the piezo actuators have been sensed, based on the piezo actuators sensing signals. In other words, when the first piezo actuators to the third piezo actuators are sequentially touched, the voltage values when the piezo actuators were touched may sequentially show peak values, as shown in FIG. 5. Thus, it may be possible to determine whether the piezo actuators have been touched based on the sensing signals.

Further, it may be possible to determine the times at which the piezo actuators were touched, by measuring the interval between the peak values. In other words, when the intervals between the peak values are smaller than the reference time, the controller may be configured to determine that the user rapidly touched the piezo actuators. Additionally, when the intervals between the peak values are greater than the reference time, the controller may be configured to determine that the user slowly touched the piezo actuators.

As described above, the controller may be configured to appropriately operate the equipment (e.g., an air conditioner or audio equipment) within a vehicle which may be connected with the safety button, using the sensing signals of the piezo actuators. The operation method of the safety button according to an exemplary embodiment of the present invention is described hereafter in detail with reference to FIGS. 4 and 5.

When the safety button is provided for operating the volume of audio equipment within a vehicle and the sensing time of the piezo actuators is greater than the reference time, the volume control gaps may be set by the controller to be substantially small (e.g., the volume control gaps may be reduced by the controller). When the sensing time of the piezo actuators is greater than the reference time, the volume control gaps may be set by the controller to be substantially large (e.g., the volume control gaps may be increased by the controller).

As another exemplary embodiment, when the safety button is provided for operating an air conditioner in a vehicle and the sensing time of the piezo actuators is greater than the reference time, the temperature control gaps may be set by the controller to be substantially small (e.g., the temperature control gaps may be decreased by the controller). When the sensing time of the piezo actuators is less than the reference time, the temperature control gaps may be set by the controller to be substantially large (e.g., the temperature control gaps may be increased by the controller).

The curved display with the safety button according to an exemplary embodiment of the present invention may function as a user interface. For example, when the safety button is provided for operating the volume of audio equipment within a vehicle and the third piezo actuator of the safety button corresponds to a maximum volume, a user may touch (e.g., contact, apply pressure to, and the like) the first piezo actuator and then sequentially may touch the second piezo actuator and the third actuator. The controller may be configured to provide the user with haptic feedback by vibrating the fourth piezo actuator, when the touch of the third piezo actuator is sensed. As described above, when feeling the vibration of the fourth piezo actuator, the user may disengage the safety button.

According to the curved display with the safety button according to an exemplary embodiment of the present invention, since the piezo actuators may be arranged at regular intervals on a front of the curved screen, a physical button may stably work, even when a touch sensor fails. Further, since haptic feedback may be provided, when a user operates the safety button, the user interface may be enhanced.

While this invention has been described in connection with what is presently considered to be exemplary embodiments, it is to be understood that the invention is not limited to the disclosed embodiments, but, on the contrary, is intended to cover various modifications and equivalent arrangements included within the spirit and scope of the accompanying claims.

What is claimed is:

1. A curved display comprising:
a curved screen configured to display an image;
a safety button that includes a plurality of piezo actuators arranged at predetermined intervals along a guide part on the curved screen; and
a controller configured to operate equipment within a vehicle based on sensing the piezo actuators and operate the piezo actuators.

2. The curved display of claim 1, wherein the controller is configured to adjust control gaps of the equipment within a vehicle by measuring a sensing time of adjacent piezo actuators.

3. The curved display of claim 2, wherein when the safety button is provided for operating the volume of audio equipment, the controller is configured adjust the volume control gaps of the audio equipment based on the sensing time of the piezo actuators.

4. The curved display of claim 2, wherein when the safety button is provided for operating the temperature of an air conditioner, the controller is configured to adjust the temperature control gaps of the air conditioner based on the sensing time of the piezo actuators.

5. The curved display of claim 1, wherein when a specific piezo actuator is sensed, the controller is configured to provide haptic feedback via the piezo actuator.

6. The curved display of claim 1, wherein a mark that shows the operation direction of the safety button is displayed on the guide part.
